(19) United States
(12) Patent Application Publication
(10) Pub. No.: US 2006/0214282 A1
(43) Pub. Date: Sep. 28, 2006

(54) Flexible printed wiring board, method for fabricating flexible printed wiring board, and semiconductor device

(75) Inventor: Ken Sakata, Shinagawa-ku (JP)

Correspondence Address: THE WEBB LAW FIRM, P.C., 700 KOPPERS BUILDING, 436 SEVENTH AVENUE, PITTSBURGH, PA, 15219, US

(73) Assignee: Mitsui Mining & Smelting Co., Ltd., Shinagawa-ku (JP)

(21) Appl. No.: 11/385,194

(22) Filed: Mar. 21, 2006

(30) Foreign Application Priority Data
Mar. 22, 2005 (JP) 2005-081581

(51) Int. Cl. H01L 23/053; H01L 21/00

(52) U.S. Cl. 257/701; 257/E23.056; 257/E23.065; 438/125

(57) ABSTRACT

A flexible printed wiring board comprises a wiring pattern that is made of conductive metal on the surface of an insulating base film and that is protected by bonding an insulating cover layer film to the surface of the wiring pattern in such a manner that the terminal section of the wiring pattern is exposed, wherein the size of the cover layer film is specified previously in such a manner that the shape of the cover layer film is almost same as that of the wiring pattern area from which the terminal section is excluded, from a viewpoint of projection, and the cover layer film is bonded to the wiring pattern area from which the terminal section is excluded. Also disclosed is a method for fabricating a flexible printed wiring board, and a semiconductor device, all that can prevent film edges from peeling and bubbles from being formed in a cover layer film when the cover layer film is bonded to the surface of the wiring pattern.

### FIELD OF THE INVENTION

The present invention relates to a flexible printed wiring board, a method for fabricating a flexible printed wiring board, and a semiconductor device. More particularly, the present invention relates to a flexible printed wiring board, a method for fabricating a flexible printed wiring board, and a semiconductor device, all which are suitable for driving an FPD (Flat Panel Display), a printer, and so on.

### BACKGROUND OF THE INVENTION

A film carrier tape for mounting an electronic component such as a TAB (Tape Automated Bonding) tape, a COF (Chip on Film) tape, a BGA (Ball Grid Array) tape, a CSP (Chip Size Package) tape, and an ASIC (Application Specific Integrated Circuit) tape, or a sheet-shaped FPC (Flexible Printed Circuit) is used for mounting an electronic component such as an IC (Integrated Circuit) into an electronic device. Such a flexible printed wiring board is manufactured by forming a conductive metal layer such as a copper foil on an insulation film such as a polyimide film, coating a photosensitive resin on the surface of the conductive metal layer, forming a pattern made of the photosensitive resin by exposing and developing the photosensitive resin for configuring a desired pattern, and forming a wiring pattern by selectively etching the conductive metal using the formed photosensitive resin pattern as a masking material.

After the wiring pattern is formed, a cover layer film is bonded to the formed wiring pattern to protect this wiring pattern.

Patent Reference 1:

Japanese Patent Laid-Open Publication No. 282650/2003

### DISCLOSURE OF THE INVENTION

### Problems to be Solved by the Invention

The following method has been adopted to bond the cover layer film to the surface of the wiring pattern.

For instance, as shown in FIG. 2, a wiring pattern 4 is formed on the surface of an insulating base film 2 in a flexible printed wiring board 6. A dummy pattern 64 composed of three wires is formed on the left lower area in a flexible printed wiring board 6. A cut rectangular cover layer film 10 having an adhesive is prepared to be bonded to the flexible printed wiring board 6. The cover layer film 10 consists of an insulating resin film substrate 9 and a film adhesive layer 8. As shown in FIG. 3, the film adhesive layer 8 of the cover layer film 10 is located to face to the wiring pattern 4, and the cover layer film 10 is then softly bonded downward with a thermocompression method by using the specified metal mold to provisionally attach the cover layer film 10 to the surface of the wiring pattern 4.

After the cover layer film 10 is provisionally attached to the wiring pattern 4, the cover layer film 10 is firmly bonded by the metal mold while being heated as shown in FIG. 4. That is to say, by second compressing downward the cover layer film 10, the film adhesive layer 8 enters between the wiring pattern 4 on the base film 2, thus ensuring reliable adhesion of the cover layer film 10 on the wiring pattern 4.

However, when the cover layer film 10 is provisionally attached to the wiring pattern 4, as shown in FIG. 3, the edge 10a of the cover layer film 10 may float partially at the corners of the cover layer film 10 in the event that the wiring pattern 4 is not formed at the edge 10a of the cover layer film 10. If the edge 10a floats from the base film 2, the cover layer film 10, which was provisionally attached to the wiring pattern 4, may peel off the base film 2. Or, since the adhesion surface of the film adhesive layer 8 includes irregularities such as a depression and a protrusion, bubbles 12 may be formed in the film adhesive layer 8 at the second firm bonding as shown in FIG. 4, thus resulting in failure products.

The present invention has been made in order to solve the above problems. An object of the present invention is to provide a flexible printed wiring board, a method for fabricating a flexible printed wiring board, and a semiconductor device, all that can prevent film edges from peeling and bubbles from being formed in the cover layer film when the cover layer film is bonded to the surface of the wiring pattern.

### Means for Solving the Problems

A flexible printed wiring board related to the present invention comprises a wiring pattern that is made of conductive metal on the surface of an insulating base film and that is protected by bonding an insulating cover layer film to the surface of the wiring pattern in such a manner that the terminal section of the wiring pattern is exposed, wherein the size of the cover layer film is specified previously in such a manner that the shape of the cover layer film is almost same as that of the wiring pattern area from which the terminal section is excluded, from a viewpoint of projection, and the cover layer film is bonded to the wiring pattern area from which the terminal section is excluded.

A method for fabricating a flexible printed wiring board related to the present invention comprises:

forming a wiring pattern that is made of conductive metal on the surface of an insulating base film, and

protecting the wiring pattern by bonding an insulating cover layer film to the surface of the wiring pattern in such a manner that the terminal section of the wiring pattern is exposed; and further comprises:

preparing a cover layer film of which the size is specified previously in such a manner that the shape of the cover layer film is almost same as that of the wiring pattern area from which the terminal section is excluded, from a viewpoint of projection, and

bonding the cover layer film to the wiring pattern area from which the terminal section is excluded.

By the above configuration, since a wiring pattern is formed under any part of the cover layer film, the edges, especially four corners, of the cover layer film do not float during provisional attaching to the wiring pattern, thus preventing bubbles from being formed in the cover layer film.

In a flexible printed wiring board related to the present invention, the cover layer film is made of a resin same as that forming the insulating base film.

In a method for fabricating a flexible printed wiring board related to the present invention, the cover layer film is made of a resin same as that forming the insulating base film.

Adopting the same type of resin as described above is suitable for lowering costs and simplifying management, and can reduce influence caused by temperature fluctuation, such as a warpage.

A semiconductor device related to the present invention comprises the flexible printed wiring board as defined above on which an electronic component is mounted.

A method for fabricating a semiconductor device related to the present invention comprises,

preparing the flexible printed wiring board obtained by the method for fabricating a flexible printed wiring board as defined above, and

mounting an electronic component on the flexible printed wiring board.

A cover layer film related to the present invention is characterized by that the size of the cover layer film is specified previously in such a manner that the shape of the cover layer film is almost same as that of the wiring pattern area formed in the flexible printed wiring board from which the terminal section is excluded, from a viewpoint of projection, and that the cover layer film is punched by using a punch and a punch hole having thus previously specified shape, wherein the cover layer film is bonded to the wiring pattern area from which the terminal section is excluded.

### Effects of the Invention

By the flexible printed wiring board related to the present invention, the shape of the cover layer film is almost same as that of the wiring pattern area from which the terminal section is excluded. Therefore, since a wiring pattern exists under any part of the cover layer film when the cover layer film is bonded to the surface of the wiring pattern, the cover layer film can be prevented from peeling or floating and bubbles can be prevented from being formed in the cover layer film, thus ensuring reliable provisional attaching and following firm bonding of the cover layer film.

### BRIEF DESCRIPTION OF THE DRAWINGS

FIG. 1 is a plan view showing a flexible printed wiring board related to an embodiment of the present invention.

FIG. 2 is a plan view showing an example of a conventional flexible printed wiring board.

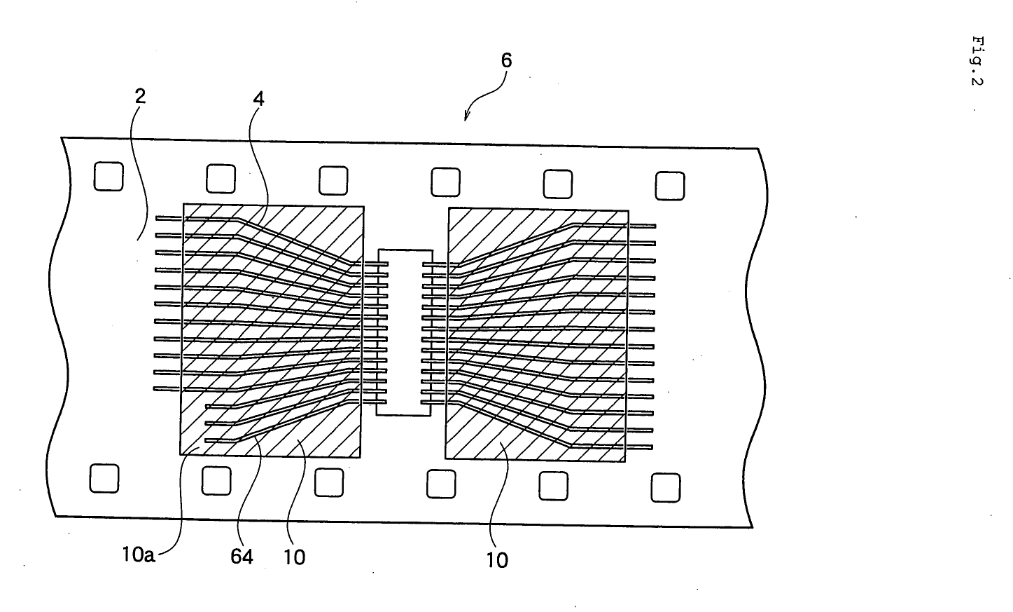

FIG. 3 is a cross-sectional view showing a conventional flexible printed wiring board to which a cover layer film is provisionally attached.

FIG. 4 is a cross-sectional view showing a conventional flexible printed wiring board to which a cover layer film was firmly bonded.

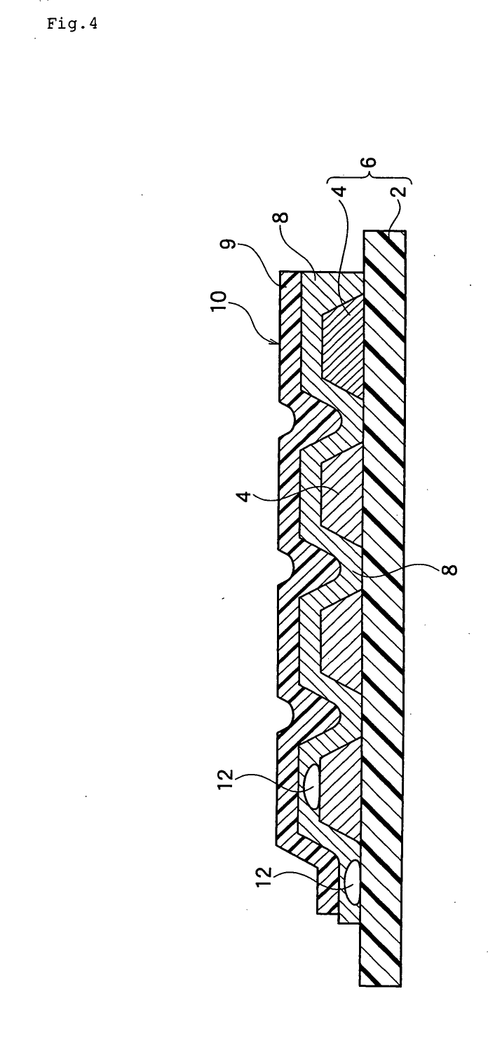

FIG. 5 is a schematic view showing the shape of punches used to punch the cover layer films and showing that one punch has a cutout section.

### ITEMS

2: Base film
4: Wiring pattern
6: Flexible printed wiring board
8: Film adhesive layer
9: Insulating resin film substrate
10: Cover layer film
10a: Edge
12: Bubble
20: Flexible printed wiring board (Film carrier tape for mounting an electronic component)
22: Base film
24: Wiring pattern
25: Dummy wiring
26: Terminal section
28: Sprocket hole
30: Device hole
32: Cover layer film (insulating resin protective film)
64: Dummy pattern
A: Punch
B: Punch
C: Corner section
L: Wiring pattern area

### BEST MODE FOR CARRYING OUT THE INVENTION

An embodiment (example) of a flexible printed wiring board, a method for fabricating a flexible printed wiring board, and a semiconductor device related to the present invention will be described below with reference to the drawings. A wiring pattern in the present invention includes a dummy pattern (dummy wiring).

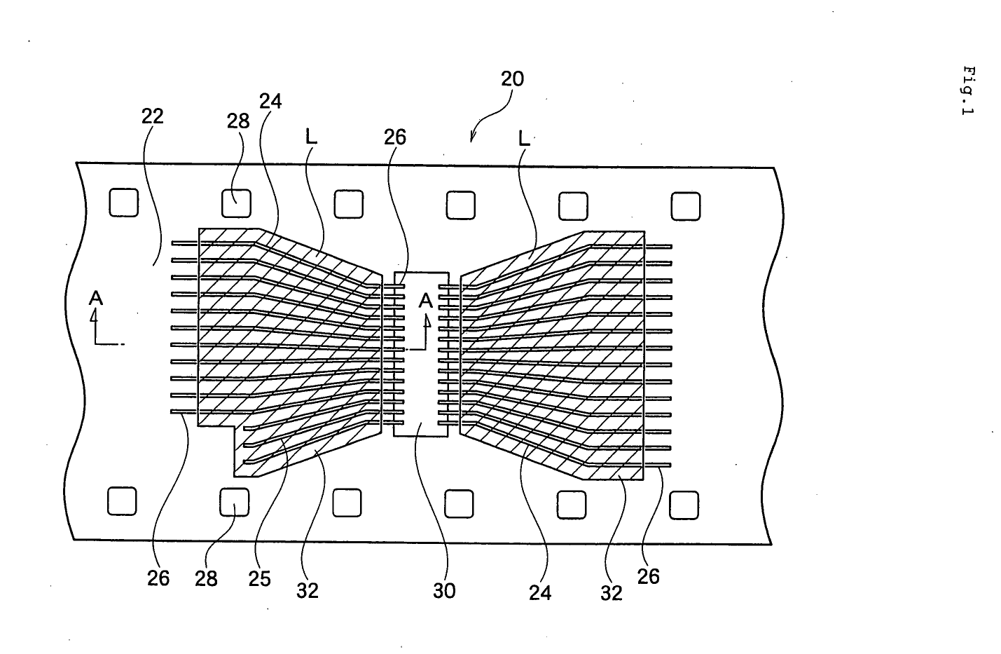

As shown in FIG. 1, a flexible printed wiring board 20 related to this embodiment consists of an insulating base film 22, a wiring pattern 24 formed on the surface of the base film 22, and a cover layer film (insulating resin protective film) 32 located on the wiring pattern 24 in such a manner that the terminal section 26 of the wiring pattern 24 is exposed. A dummy pattern (dummy wiring) that is not electrically connected to an electronic component can be formed in the flexible printed wiring board 20.

For the insulating base film 22, materials such as a polyimide film, a polyimide amide film, a polyester film, a polyphenylene sulfide film, a polyether imide film, a fluorocarbon polymer film, and a liquid crystal polymer film can be used. The insulating base film 22 has acid resistance and alkali resistance so as not to be corroded by an etching solution used for etching or an alkali solution used for washing, and has heat resistance so as not to be greatly deformed due to heat during mounting of an electronic component. The polyimide film is more suitable for the insulating base film 22 having such properties.

The average thickness of the insulating base film 22 is in the range of 5 to 150 μm in general, 5 to 125 μm preferably, 25 to 75 μm preferably in particular.

Some required holes such as sprocket holes 28, a device hole 30, a slit for bending (not shown), and a hole for alignment (not shown) are formed by punching in the above-mentioned insulating base film 22.

The wiring pattern 24 is formed by selectively etching conductive metal located on the above-mentioned base film 22. Conductive metal that is used herein is, for example, copper, copper base alloy, aluminum, or aluminum base alloy. Such conductive metal can be located on the surface of the base film 22 by a process such as deposition or metal plating. In addition, a metal layer made of the above conductive metal can also be attached to the base film 22. The thickness of the above conductive metal layer is in the range of 2 to 70 μm in general, 5 to 45 μm preferably.

The conductive metal layer as described above can also be located on the surface of the insulating base film 22 without using an adhesive. An adhesive layer that is used for the adhesion of the conductive metal layer of a three-layer tape is made of an epoxy resin adhesive, a polyimide resin adhesive, or an acrylic resin adhesive, etc. The thickness of the above adhesive layer is in the range of 5 to 50 μm in general, 10 to 40 μm preferably. Such an adhesive layer is not generally incorporated in a two-layer tape.

The wiring pattern 24 is formed by selectively etching the conductive metal layer formed on the surface of the insulating base film 22 as described above. That is to say, a photosensitive resin layer is coated on the surface of the conductive metal layer, and is exposed and developed to form a desired photosensitive resin pattern. By using the desired photosensitive resin pattern as a masking material, the wiring pattern 24 can be formed by selectively etching the conductive metal layer.

Insulating cover layer films 32 are bonded to the surface of the wiring pattern 24 fabricated as described above in such a manner that only a terminal section 26 is exposed and other parts of the wiring pattern 24 are covered by the insulating cover layer films 32.

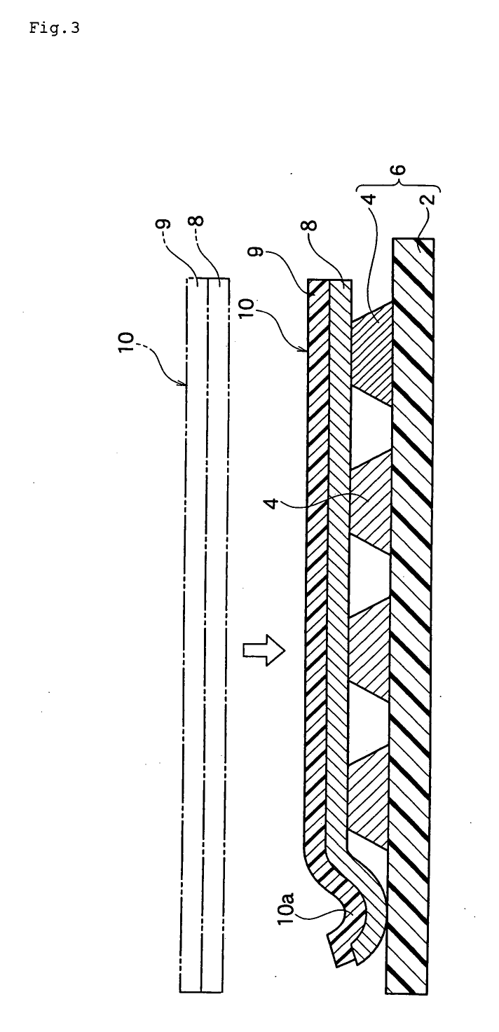

Similarly to the cover layer film 10 as shown in FIG. 3, the cover layer film 32 consists of an insulating resin film substrate 9 and a film adhesive layer 8 which is formed on one side of the insulating resin film substrate 9.

As shown in FIG. 1, the shape of the cover layer film 32 related to this embodiment is set to almost same as that of the wiring pattern area L from which the terminal section 26 is excluded, from a viewpoint of projection.

In detail, the cover layer film 32 is cut along the line expanded by the range of 100 μm to 3 mm from the outermost wiring of the wiring pattern 24.

The cover layer film 32 is prepared in advance. As a result, when the cover layer film 32 is provisionally attached and then firmly bonded to the wiring pattern 24, the formation of bubbles and the floating or peeling of the cover layer film 32 which have conventionally occurred can be prevented effectively.

Conventionally, a large rectangular cover layer film including the section under which a wiring pattern 24 does not exist is prepared and bonded so as to cover the wiring pattern 24. As a result, since the cover layer film 32 is also bonded to the area where no wiring pattern is formed (at four corners in particular), irregularities such as a depression and a protrusion occurred on the adhesion surface in provisional attaching and bubbles were then formed in firm bonding in the flexible printed wiring board of 40 to 50 percent. As a countermeasure related to this embodiment, since the cover layer film section under which a wiring pattern 24 does not exist is cut in advance, the occurrence rate of bubbles is only 0 to 1 percent for the flexible printed wiring board after firm bonding, thus almost completely preventing bubbles from occurring.

The flexible printed wiring board related to this embodiment is suitable for equipment such as an FPD (Flat Panel Display) device and a printer as described earlier.

For the heat resistance protective resin configuring the insulating resin film substrate 9 of the cover layer film 32, material such as a polyimide resin, a polyalkylene terephthalete resin, a polyalkylene naphthalete resin, and an aramide resin can be used. The combination of the above resins can also be used for the insulating resin film substrate 9. The average thickness of the insulating resin film substrate 9 made of the heat resistance protective resin is equivalent to or larger than 1 μm in general, in the range of 3 to 75 μm preferably, 4 to 50 μm preferably in particular.

For the film adhesive layer 8 made of a thermosetting resin coated on the insulating resin film substrate 9 described above, a thermosetting resin such as an epoxy resin, a polyimide precursor (polyamide acid), and a phenol resin can be used. In particular, a hardening temperature of a thermosetting adhesive made of a thermosetting resin used in this embodiment is in the range of 80 to 200 degrees centigrade in general, 130 to 180 degrees centigrade preferably. In addition, the adhesive property on the surface of the thermosetting adhesive does not occur in a room temperature, but the adhesive property occurs preferably when the thermosetting resin is heated for adhesion. Further, the thermosetting adhesive that was hardened after heated should have elasticity. To make the thermosetting adhesive elastic, elastomer is blended to a thermosetting resin that is an adhesive component, or a thermosetting resin is modified by an elastomer component to make the hardened thermosetting resin elastic.

A thickness of the film adhesive layer 8 should be equivalent to or larger than that of the conductive metal layer located on the surface of the base film 22 to form the wiring pattern 24, and is in the range of 10 to 50 μm in general, 20 to 50 μm preferably. By specifying the thickness of the film adhesive layer 8 to the above range, when the cover layer film 32 is punched and bonded to the surface of the wiring pattern 24, gaps between adjacent wires can be filled with an adhesive, thus preventing unnecessary airspaces from being formed between the wiring pattern and the bonded cover layer film 32.

A thickness of the above configured cover layer film 32 related to this embodiment (the total thickness of the film adhesive layer 8 and the insulating resin film substrate 9) is in the range of 15 to 125 μm in general, 15 to 75 μm preferably. The cover layer film 32 has been wound upon a feeding reel in advance. The cover layer film 32 is then fed from the feeding reel in such a manner that the side of the film adhesive layer 8 of the cover layer film 32 faces to the surface of the wiring pattern 24 on the base film 22. The cover layer film 32 is punched by a punching press apparatus provided with a punch and a punch hole having a shape same as that of the cover layer film to be punched. A piece of the cover layer film 32 that was punched with the above punching press apparatus is located on the position specified for forming a cover layer protective film of the flexible printed wiring board which moves along a guide unit. The cover layer film 32 is heated up to 60 to 120 degrees centigrade, and attached provisionally to the wiring pattern 24 at a pressure in the range of 0.2 to 2 MPa, preferably 0.4 to 0.8 MPa. The cover layer film 32 is then heated up to the range of 100 to 200 degrees centigrade, preferably 130 to 180 degrees centigrade, and bonded firmly to the wiring pattern 24 at a pressure in the range of 0.3 to 5 MPa, preferably 0.6 to 0.9 MPa according to the type of the film adhesive layer 8.

A metal mold for firm bonding is provided with an elastic member made of a silicon resin or fluorocarbon polymer, through which the surface of the wiring pattern 24 is pressed. The above punched cover layer film 32 is wound upon a take-up reel.

The section of the cover layer film 32 under which the wiring pattern 24 is not formed has been removed, and the cover layer film 32 is bonded to only the area where the wiring pattern 24 is formed. As a result, the flexible printed wiring board 20 fabricated as described above can prevent bubbles from being formed and films from peeling.

For a semiconductor device related to the present invention, an electronic component is mounted in the device hole 30 of the flexible printed wiring board as described above and sealed by a resin.

Although an embodiment of the present invention has been described above, this invention is not restricted to the above embodiment.

For instance, although two cover layer films 32 and 32 with the almost same size are used in the above embodiment, the size and shape of the cover layer films can be different. In addition, the two cover layer films can be integrated (a one-body cover layer film can be formed).

That is to say, the cover layer film 32 should not be bonded to the area where the wiring pattern 24 is not formed, and any shape of the cover layer film can be adopted according to the shape of the wiring pattern 24.

### Embodiments

An embodiment of the present invention is described below; however, the present invention is not restricted to the embodiment.

### Embodiment 1

An electrodeposited copper foil with an average thickness of 35 μm was laminated by thermocompression to a polyimide film with a thickness of 50 μm (product name: UPILEX S, manufactured by UBE INDUSTRIES, LTD.) through an adhesive layer with a thickness of 12 μm.

A photosensitive resin was then coated on the electrodeposited copper foil, and the photosensitive resin was cured, exposed, and developed to make a desired etching-resist pattern.

A base film on which the photosensitive resin pattern was formed was treated with an etching solution, and the electrodeposited copper foil was selectively etched-using the photosensitive resin pattern as a masking material, thus forming the wiring pattern made of copper.

On the other hand, a phenol adhesive with a thickness of 35 μm was coated on a polyimide resin film with a thickness of 12 μm to make a cover layer film.

The adhesive layer of the cover layer film fabricated as described above was located so as to face to the surface of the wiring pattern in the film carrier tape for mounting an electric component and was punched by a punching press apparatus provided with a punch and a punch hole. The cover layer film was then heated up to 100 degrees centigrade, and attached to the specified position of the wiring pattern at a pressure of 0.5 MPa.

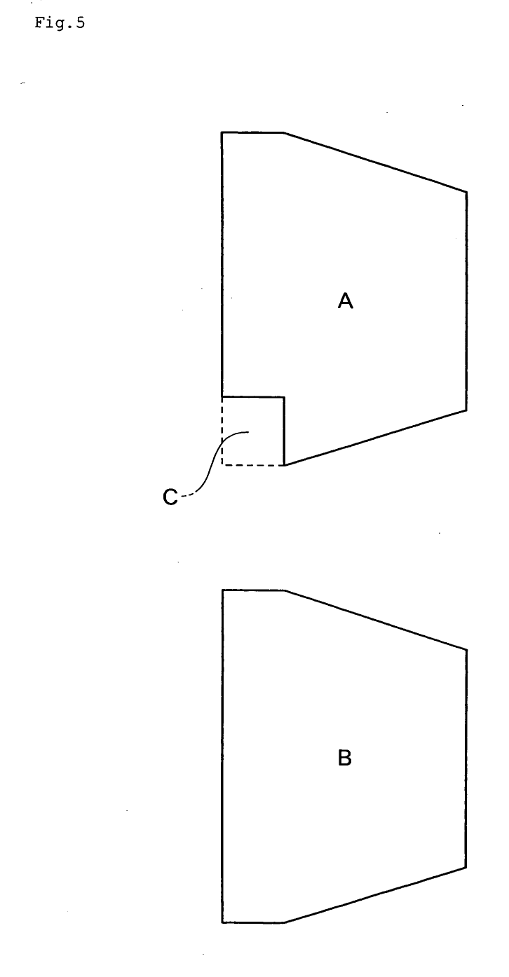

Two punches A and B were prepared as shown in FIG. 5. A section C was cut from the corner of punch A, however, punch B was not cut. The shape on the whole and material of the punch A are equivalent to those of the punch B. The punches A and B were set to the press apparatus, and two cover layer films were punched simultaneously to be the shapes of punches A and B at once. A film piece that was punched by punch A was located on the left side in FIG. 1, that is, on the area where three dummy wiring 25 are formed. On the other hand, a film piece that was punched by punch B was located on the right side in FIG. 1. The two films were bonded to the wiring pattern immediately after the punching.

As described above, the cover layer films corresponding to the shapes of punches A and B were provisionally attached to the left and right wiring patterns on the base film respectively as shown in FIG. 1, thus making samples of ten thousand pieces. The corners of any cover layer film samples were flat, and irregularities such as a depression and a protrusion resulting in peeling or floating did not occur.

An elastic member made of a silicon resin (silicon pad) was attached to the surface of the metal mold for performing firm bonding before the cover layer film was firmly bonded to the base film.

This firm bonding was performed at a temperature of 170 degrees centigrade and a pressure of 0.7 MPa for 15 seconds.

No bubbles were found in the adhesion surface between the cover layer film and the wiring pattern for the film carriers of ten thousand pieces. In addition, when the bonding conditions of the cover layer film were confirmed especially at four corners of the cover layer film, the corners were flat and irregularities such as a depression and a protrusion resulting in peeling and floating were not found since appropriate bonding was performed at any corners.

### Comparative Embodiment

A base film, on which a desired wiring pattern was formed, was fabricated similarly to embodiment 1 as described above.

Two punches B having the shape shown in FIG. 5 were prepared. In this comparative embodiment, the cover layer film was set to be larger than the wiring pattern area so as to cover an area where no wiring pattern was formed as well. The film pieces that were punched by punches B and B were provisionally attached to the surface of the wiring pattern and then firmly bonded to the wiring pattern. The conditions such as a temperature and a pressure during the provisional attaching and firm bonding were the same as those specified in embodiment 1.

In this comparative embodiment, the cover layer film was bonded to the area where no wiring pattern was formed (corresponding to section C as shown in FIG. 5).

In the nearly half pieces of samples, peeling or floating occurred at the adhesion surface between the wiring pattern and the cover layer film provisionally attached to the wiring pattern as described above. In particular, for many samples, peeling or floating occurred at the corners in which the wiring pattern is not formed among the four corners of the cover layer film even if peeling or floating was not found in areas other than the four corners. In addition, bubbles occurred in forty-three percent of samples to which the cover layer film was firmly bonded.

1. A flexible printed wiring board comprising a wiring pattern that is made of conductive metal on the surface of an insulating base film and that is protected by bonding an insulating cover layer film to the surface of the wiring pattern in such a manner that the terminal section of the wiring pattern is exposed,
wherein the size of the cover layer film is specified previously in such a manner that the shape of the cover layer film is almost same as that of the wiring pattern area from which the terminal section is excluded, from a viewpoint of projection, and the cover layer film is bonded to the wiring pattern area from which the terminal section is excluded.

2. A flexible printed wiring board as claimed in claim 1, wherein the cover layer film is made of a resin same as that forming the insulating base film.

3. A semiconductor device comprising the flexible printed wiring board as claimed in claim 1 and an electronic component mounted on the flexible printed wiring board.

4. A cover layer film characterized by that the size of the cover layer film is specified previously in such a manner that the shape of the cover layer film is almost same as that of the wiring pattern area formed in the flexible printed wiring board from which the terminal section is excluded, from a viewpoint of projection, and that the cover layer film is punched by using a punch and a punch hole having thus previously specified shape,
wherein the cover layer film is bonded to the wiring pattern area from which the terminal section is excluded.

5. A method for fabricating a flexible printed wiring board comprising:
forming a wiring pattern that is made of conductive metal on the surface of an insulating base film, and
protecting the wiring pattern by bonding an insulating cover layer film to the surface of the wiring pattern in such a manner that the terminal section of the wiring pattern is exposed;
and further comprising:
preparing a cover layer film of which the size is specified previously in such a manner that the shape of the cover layer film is almost same as that of the wiring pattern area from which the terminal section is excluded, from a viewpoint of projection, and
bonding the cover layer film to the wiring pattern area from which the terminal section is excluded.

6. A method for fabricating a flexible printed wiring board as claimed in claim 5, wherein the cover layer film is made of a resin same as that forming the insulating base film.

7. A method for fabricating a semiconductor device comprising,
preparing the flexible printed wiring board obtained by the method for fabricating a flexible printed wiring board as claimed in claim 5, and
mounting an electronic component on the flexible printed wiring board.

8. A semiconductor device comprising the flexible printed wiring board as claimed in claim 2 and an electronic component mounted on the flexible printed wiring board.

9. A method for fabricating a semiconductor device comprising,
preparing the flexible printed wiring board obtained by the method for fabricating a flexible printed wiring board as claimed in claim 6, and
mounting an electronic component on the flexible printed wiring board.
